(19) United States
(12) Patent Application Publication
(10) Pub. No.: US 2013/0270713 A1
(43) Pub. Date: Oct. 17, 2013

(54) DUAL DAMASCENE STRUCTURE HAVING THROUGH SILICON VIA AND MANUFACTURING METHOD THEREOF

(71) Applicants: Sue-Chen Liao, Taichung City (TW); Tzu-Kun Ku, Hsinchu City (TW); Cha-Hsin Lin, Miaoli County (TW); Pei-Jer Tzeng, Hsinchu City (TW); Chi-Hon Ho, Tainan City (TW)

(72) Inventors: Sue-Chen Liao, Taichung City (TW); Tzu-Kun Ku, Hsinchu City (TW); Cha-Hsin Lin, Miaoli County (TW); Pei-Jer Tzeng, Hsinchu City (TW); Chi-Hon Ho, Tainan City (TW)

(73) Assignee: Industrial Technology Research Institute, Hsinchu (TW)

(21) Appl. No.: 13/545,989

(22) Filed: Jul. 11, 2012

(30) Foreign Application Priority Data
Apr. 12, 2012 (TW) 101113023

(51) Int. Cl. H01L 23/48; H01L 21/768

(52) U.S. Cl. 257/774; 438/675; 257/E21.586; 257/E23.011

(57) ABSTRACT

A dual damascene structure having a through silicon via and a manufacturing method thereof are provided. The method includes forming a first, a second, and a third dielectric layers a on a substrate having a conductive structure. A trench is formed in the third dielectric layer. A hard mask layer is formed on the third dielectric layer and a surface of the trench. A first opening having a tapered sidewall is formed in the hard mask layer. A second opening is formed in the second and the third dielectric layers. The substrate exposed by the second opening and the first opening is etched to form a through hole so as to form a dual damascene opening. A liner layer is formed on a surface of the dual damascene opening and the conductive structure is exposed. The dual damascene opening is filled with a conductive material.

### CROSS-REFERENCE TO RELATED APPLICATION

This application claims the priority benefit of Taiwan application serial no. 101113023, filed on Apr. 12, 2012. The entirety of the above-mentioned patent application is hereby incorporated by reference herein and made a part of this specification.

### BACKGROUND

1. Technical Field

The disclosure relates to a dual damascene structure having a through silicon via (TSV) and a manufacturing method thereof.

2. Related Art

In a stacked-type semiconductor device package, several semiconductor devices are perpendicularly stacked together in one package structure, so as to increase the package density and miniaturize the package. Moreover, length of signal transmission paths among semiconductor devices can be further reduced by conducting a three-dimensional stacking method; thereby, the signal transmission among the semiconductor devices can be accelerated, and the semiconductor devices with different functions can be integrated into one package. The existing stacked-type semiconductor device package is formed by stacking chips onto a wafer carrier having a TSV, so as to perform a wafer-level packaging process. Besides, after the packaging process is completed, the wafer carrier and a sealant thereon are cut to form a plurality of individual package units.

Recently, the dual damascene technique has also been applied to the TSV fabrication process. Nonetheless, once the dual damascene technique is applied to the TSV fabrication process, corners at the top portion of the TSV hole are apt to be overly etched in the steps following the formation of the TSV hole, such that the silicon substrate is exposed. As a result, when the TSV hole is filled with a metallic material in a later stage, short circuit may occur between devices in the exposed silicon substrate and the metallic material.

### SUMMARY

A manufacturing method of a dual damascene structure having a TSV is introduced herein. The manufacturing method comprises providing a substrate. The substrate has a first surface and a second surface, and a conductive structure is located on the second surface of the substrate. A first dielectric layer, a second dielectric layer, and a third dielectric layer are sequentially formed on the first surface of the substrate. A trench is formed in the third dielectric layer to expose the second dielectric layer. A hard mask layer is formed on the third dielectric layer and a surface of the trench. A photoresist layer is formed on the hard mask layer, and the photoresist layer exposes the hard mask layer in the trench. The hard mask layer is etched with use of the photoresist layer as an etching mask, so as to form a first opening in the hard mask layer. Here, the first opening has a tapered sidewall. The second dielectric layer and the first dielectric layer are etched with use of the photoresist layer and the hard mask layer as an etching mask, so as to form a second opening in the second dielectric layer and the first dielectric layer. The substrate exposed by the second opening and the first opening is etched to form a through hole in the substrate. The photoresist layer is removed to form a dual damascene opening composed of the trench and the through hole. A liner layer is formed on a surface of the dual damascene opening. The liner layer at a bottom of the dual damascene opening is removed to expose the conductive structure. The dual damascene opening is filled with a conductive material.

A dual damascene structure having a TSV is also introduced herein. The dual damascene structure comprises a substrate, a first dielectric layer, a second dielectric layer, a third dielectric layer, a hard mask layer, a conductive material, and a liner layer. The substrate has a first surface and a second surface, and a conductive structure is located on the second surface of the substrate. The first dielectric layer, the second dielectric layer, and the third dielectric layer are sequentially stacked on the first surface of the substrate, and the third dielectric layer has a trench therein. The hard mask layer is located on a surface of the trench. Here, the hard mask layer, the second dielectric layer, the first dielectric layer, and the substrate have a through hole which exposes the conductive structure. The through hole communicates with the trench to form a dual damascene opening. Besides, the through hole has a top sidewall and a bottom sidewall, and the top sidewall is not parallel to the bottom sidewall. The dual damascene opening is filled with a conductive material. The liner layer is located between the conductive material and the top sidewall and the bottom sidewall of the through hole of the dual damascene opening and located between the conductive material and a sidewall of the trench.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 to FIG. 9 are schematic flowcharts illustrating a manufacturing method of a dual damascene structure having a TSV according to an exemplary embodiment.

### DETAILED DESCRIPTION OF DISCLOSED EMBODIMENTS

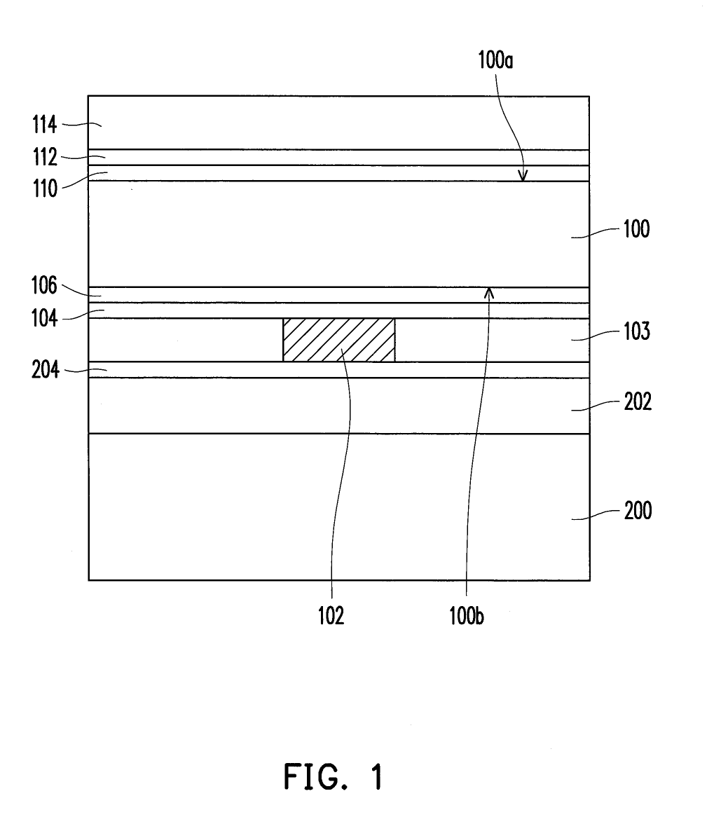

FIG. 1 to FIG. 9 are schematic flowcharts illustrating a manufacturing method of a dual damascene structure having a TSV according to an exemplary embodiment. With reference to FIG. 1, a substrate 100 is provided. The substrate 100 has a first surface 100a and a second surface 100b, and a conductive structure 102 is located on the second surface 100b of the substrate 100. In this exemplary embodiment, the substrate 100 is, for instance, a silicon substrate (e.g., a wafer) or any other appropriate substrate. Here, at least one semiconductor device (not shown) is already formed in and/or on the substrate 100. In general, the first surface 100a of the substrate 100 may be known as a back surface, and the second surface 100b of the substrate 100 may be known as a top surface. According to the present exemplary embodiment, a method of forming the conductive structure 102 on the second surface 100b of the substrate 100 comprises forming insulation layers 106, 104, and 103 on the second surface 100b of the substrate 100. There is an etching selectivity ratio between the insulation layer 104 and the other two insulation layers 106 and 103. For instance, the insulation layers 106, 104, and 103 are a silicon oxide layer, a silicon nitride layer, and a silicon oxide layer stacked together or a silicon oxide layer, a silicon oxynitride layer, and a silicon oxide layer stacked together, both of which should not be construed as limiting the disclosure. An opening (not shown) is formed in the insulation layer 103 and is filled with a conductive material to form the conductive structure 102. The conductive structure 102 may be a contact plug, a conductive line, a semiconductor device, and so on, and the conductive structure 102 is electrically connected to the semiconductor device (not shown) in or on the substrate 100. After the conductive structure 102 is completely formed, a dual damascene process is performed on the first surface 100a (i.e., the bottom surface) of the substrate 100. Before the dual damascene process is performed, a passivation layer 20 covering the conductive structure 102 may be formed on the second surface 100b of the substrate 100, and the substrate 100 may be fixed to a support device 200 through an adhesive layer 202.

A first dielectric layer 110, a second dielectric layer 112, and a third dielectric layer 114 are sequentially formed on the first surface 100a of the substrate 100. A thickness of the first dielectric layer 110, for instance, ranges from about 500 Å to about 5000 Å, and a material of the first dielectric layer 110 comprises silicon oxide, silicon nitride, a high-k dielectric material, a macromolecular polymer, or any other suitable material. A thickness of the second dielectric layer 112, for instance, ranges from about 500 Å to about 5000 Å, and a material of the second dielectric layer 112 comprises silicon oxide, silicon nitride, a high-k dielectric material, a polymer material, or any other suitable material. A thickness of the third dielectric layer 114, for instance, ranges from about 5000 Å to about 5 μm, and a material of the third dielectric layer 114 comprises silicon oxide, silicon nitride, a high-k dielectric material, a polymer material, or any other suitable material. Here, the material of the first dielectric layer 110 may be the same as the material of the third dielectric layer 114, which should however not be construed as a limitation to the disclosure. Besides, there is an etching selectivity ratio between the third insulation layer 114 and the second insulation layer 112.

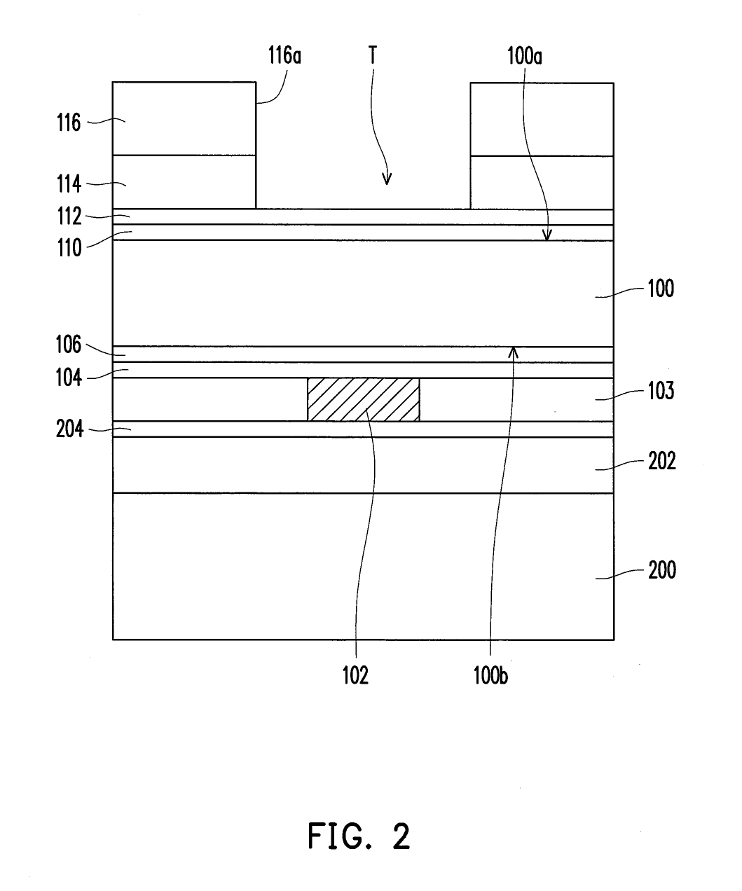

With reference to FIG. 2, a trench T is formed in the third dielectric layer 114 to expose the second dielectric layer 112. Here, a method of forming the trench T comprises forming a photoresist layer 116 on the third dielectric layer 114, and the photoresist layer 116 has an opening 116a. The third dielectric layer 114 is then etched with use of the photoresist layer 116 as an etching mask, so as to form the trench T, and the trench T exposes the second dielectric layer 112. Here, there is a sufficient etching selectivity ratio between the third insulation layer 114 and the second insulation layer 112. Hence, the step of etching the third dielectric layer 114 may be stop on the second dielectric layer 112.

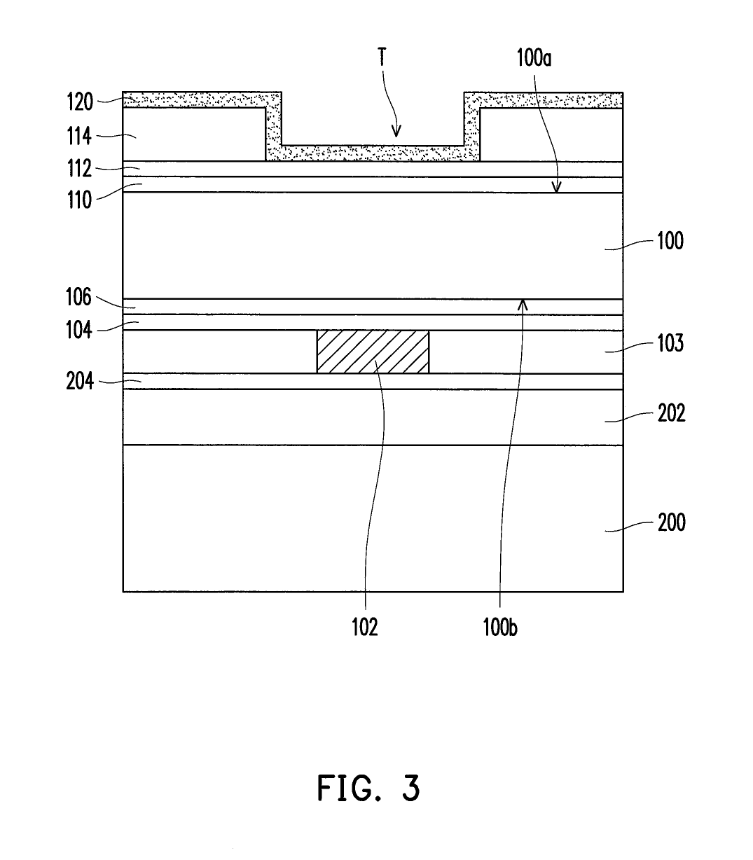

With reference to FIG. 3, after the photoresist layer 116 is removed, a hard mask layer 120 is formed on the third dielectric layer 114 and a surface of the trench T. Here, a method of forming the hard mask layer 120 comprises plasma-enhanced chemical vapor deposition (PECVD), sub-atmospheric chemical vapor deposition (SA-CVD), high density plasma chemical vapor deposition (HDP-CVD), spin coating, physical vapor deposition (PVD) or any other suitable process. A thickness of the hard mask layer 120 ranges from about 500 Å to about 5000 Å; therefore, the hard mask layer 120 may conformally cover the third dielectric layer 114 and the surface of the trench T. A material of the hard mask layer 120 comprises amorphous silicon carbide, silicon nitride, silicon oxynitride, polyimide, tetra-ethyl-ortho-silicate (TEOS) oxide, benzocyclobutene (BCB), or polybenzoxazole (PBO) or any other suitable material. In addition, the hard mask layer 120 may have a single-layer structure or a multi-layer structure. The material of the hard mask layer 120 may be the same as the material of the second dielectric layer 112, which should however not be construed as a limitation to the disclosure.

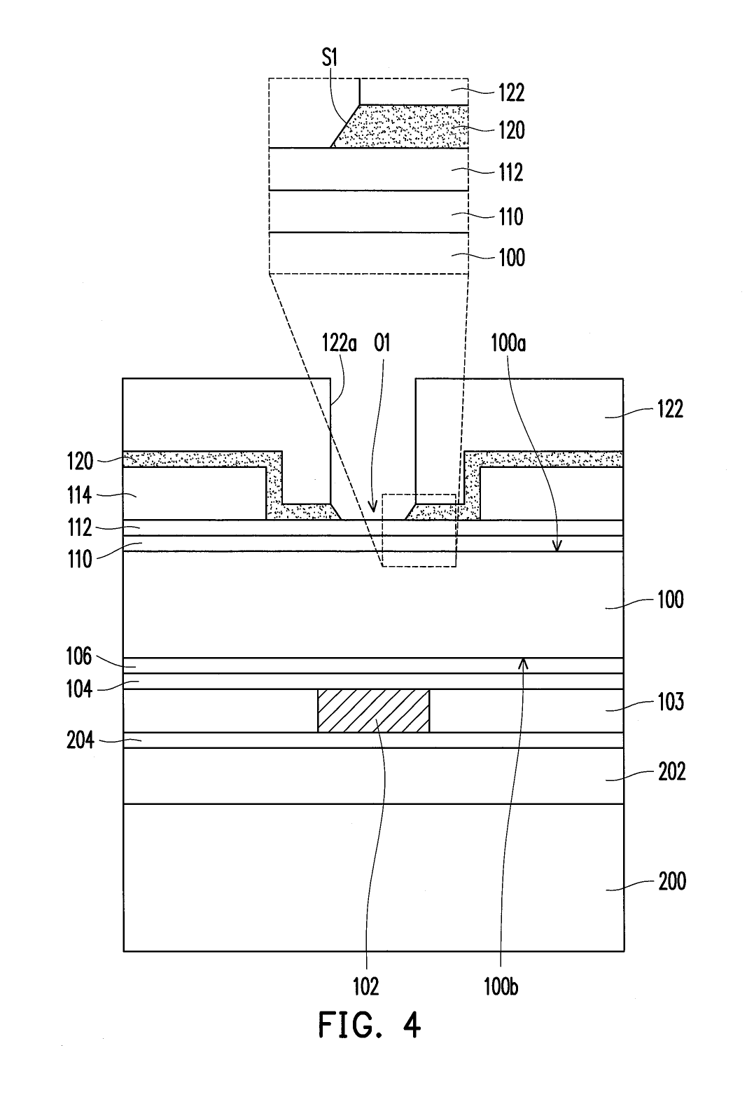

With reference to FIG. 4, a photoresist layer 122 is formed on the hard mask layer 120. The photoresist layer 120 has an opening 120a to expose the hard mask layer 120 in the trench T. The hard mask layer 120 is etched with use of the photoresist layer 122 as an etching mask, so as to form a first opening O1 in the hard mask layer 120. Here, the first opening O1 has a tapered sidewall S1. Namely, the tapered sidewall S1 of the first opening O1 is not parallel to the sidewall of the opening 122a of the photoresist layer 122, i.e., there is an obtuse included angle between the tapered sidewall S1 of the first opening O1 and the sidewall of the opening 122a of the photoresist layer 122. According to the present exemplary embodiment, etching parameters may be adjusted to equip the first opening O1 of the hard mask layer 120 with the tapered sidewall S1, and the etching parameters comprise an introduced gas ratio, a radio frequency bias, power, etching time, and so forth.

It should be mentioned that the etching step performed on the hard mask layer 120 allows the first opening O1 of the hard mask layer 120 to have the tapered sidewall S1. According to another exemplary embodiment, if the etching step is performed for a relatively long period, the first opening O1 may further extend into the second dielectric layer 112. That is, the first opening O1 having the tapered sidewall S1 not only can pass through the hard mask layer 120 but also can further extend to the second dielectric layer 112 or even pass through the second dielectric layer 112.

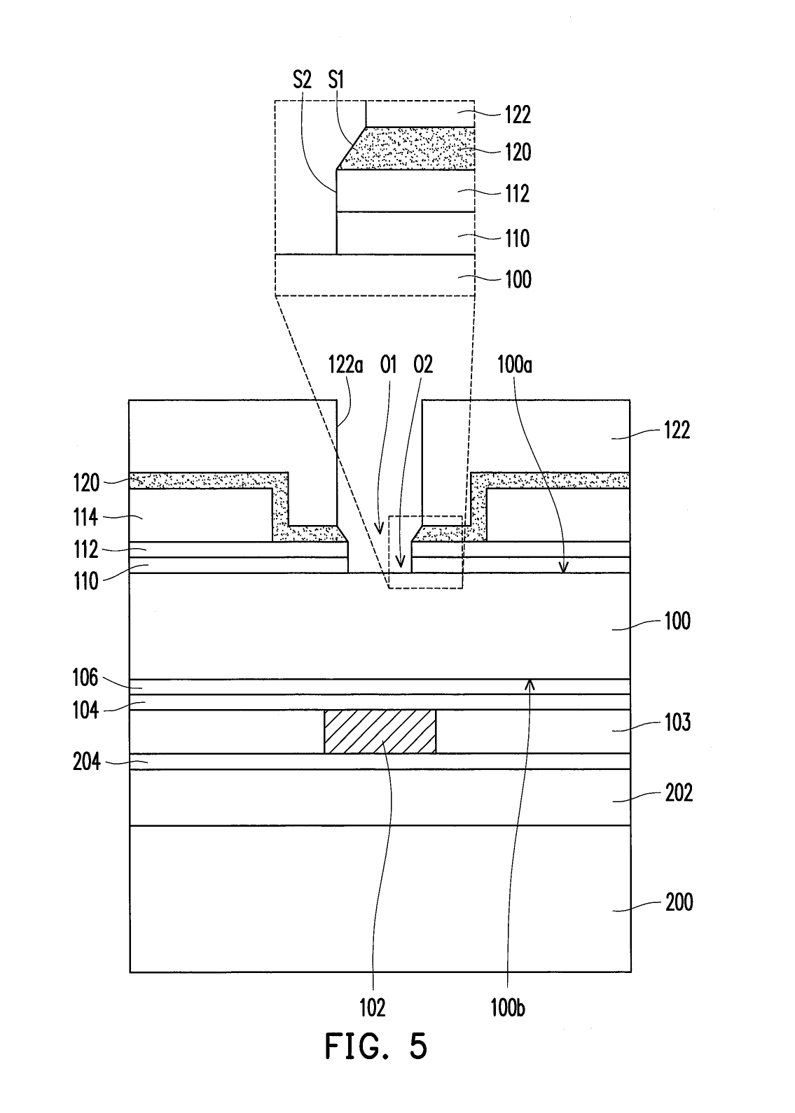

With reference to FIG. 5, the second dielectric layer 112 and the first dielectric layer 110 are etched with use of the photoresist layer 122 and the hard mask layer 120 as an etching mask, so as to form a second opening O2 in the second dielectric layer 112 and the first dielectric layer 110. In the present exemplary embodiment, the second opening O2 substantially has a vertical sidewall. Namely, the tapered sidewall S1 of the first opening O1 is not parallel to the vertical sidewall S2 of the second opening O2, i.e., there is an obtuse included angle between the tapered sidewall S1 of the first opening O1 and the vertical sidewall S2 of the second opening O2. According to the present exemplary embodiment, etching parameters may be adjusted to equip the second opening O1 of the second dielectric layer 112 and the first dielectric layer 110 with the vertical sidewall S2, and the etching parameters comprise an introduced gas ratio, a radio frequency bias, power, etching time, and so forth.

It should be mentioned that the second opening O2 having the vertical sidewall S2 is formed in the first dielectric layer 110 and the second dielectric layer 112. According to another exemplary embodiment, if the first opening O1 having the tapered sidewall S1 not only passes through the hard mask layer 120 but also extends to the second dielectric layer 112, the second opening O2 having the vertical sidewall S2 is formed in the first dielectric layer 110.

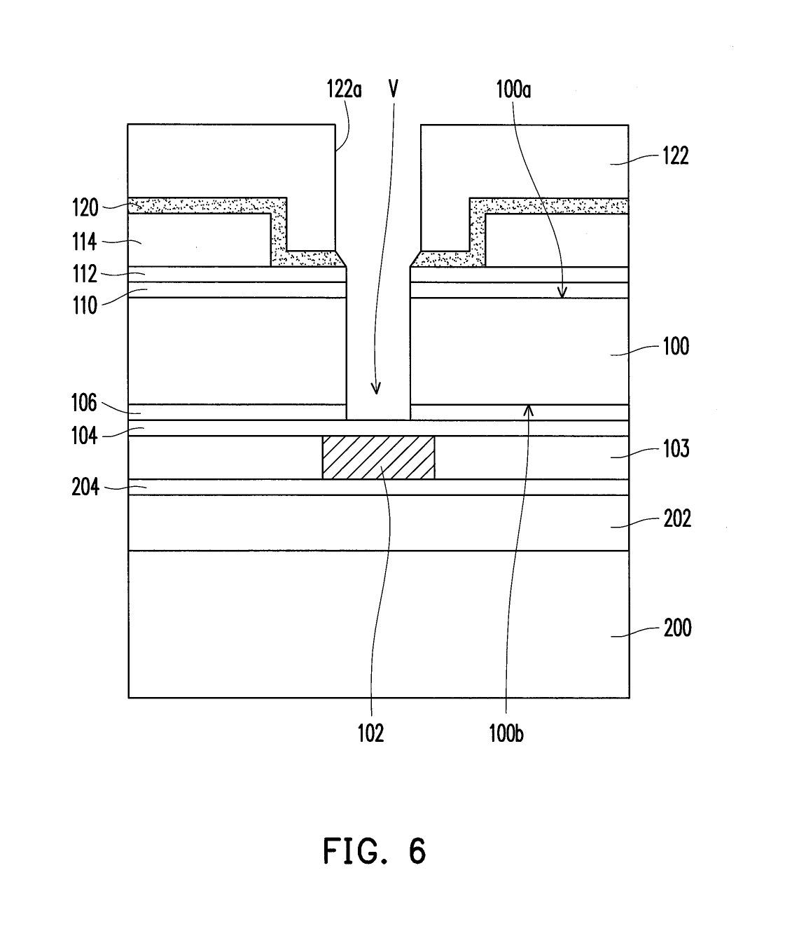

The substrate 100 exposed by the second opening O2 and the first opening O1 is etched to form a through hole V in the substrate 100, as shown in FIG. 6. Since the through hole V passes through the substrate 100, the through hole V may be known as a TSV hole. In the present exemplary embodiment, a method of forming the through hole V comprises etching the substrate 100 exposed by the second opening O2 and the first opening O1 with use of the photoresist layer 122 and the hard mask layer 120 as an etching mask. The etching step performed on the exposed substrate 100 may be a Bosch-type deep reactive ion etching step, for instance. The insulation layer 106 underlying the substrate 100 is then etched in the same etching step, while the same etching step is stop on the insulation layer 104. At this time, the through hole V formed by performing said etching step exposes the insulation layer 104.

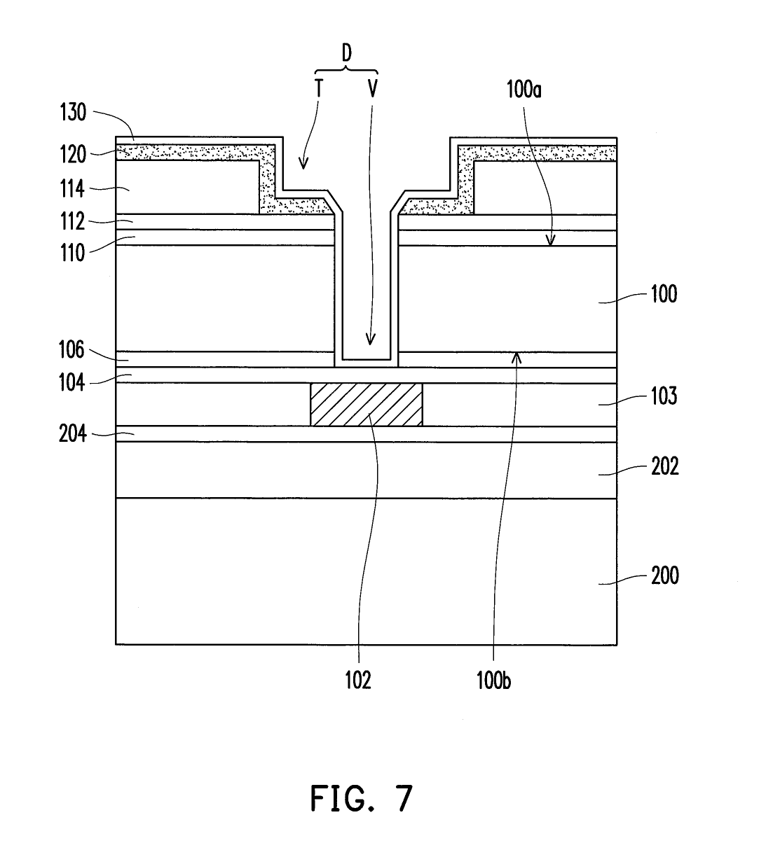

The photoresist layer 122 is removed to form a dual damascene opening D composed of the trench T and the through hole V, as shown in FIG. 7. A liner layer 130 is formed on a surface of the dual damascene opening D. A method of forming the liner layer 130 comprises performing a PECVD process or a low-temperature CVD process, for instance. A thickness of the liner layer 130, for instance, ranges from about 500 Å to about 5 μm. The liner layer 130 comprises an insulation material, e.g., silicon oxide, silicon nitride, a high-k dielectric material, a polymer material, or any other suitable material with a high etching selectivity ratio. Here, the liner layer 130 conformally covers the surface of the dual damascene opening D. In particular, the first opening O1 of the hard mask layer 120 has the tapered sidewall S1, as shown in FIG. 5, the liner layer 130 conformally covers the tapered sidewall S1. If the liner layer 130 is formed by performing the low-temperature CVD process, note that the resultant liner layer 130 has relatively low step coverage. Accordingly, the liner layer 130 located at a bottom of the dual damascene opening D may have a relatively thin thickness, which is conducive to implementation of the subsequent etching process.

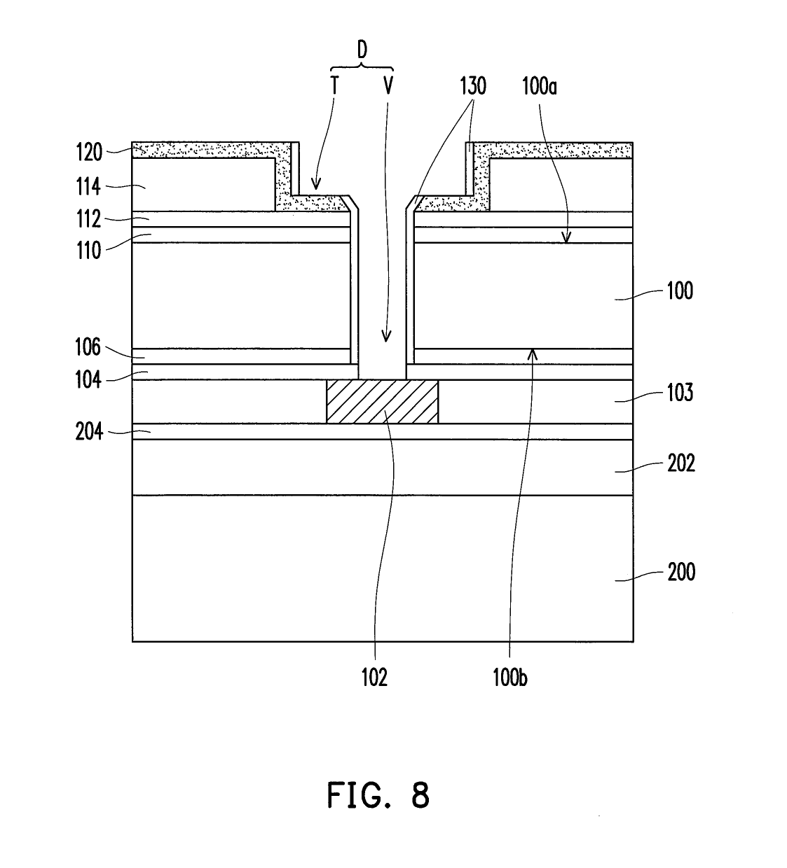

The liner layer 130 at the bottom of the dual damascene opening D is removed to expose the conductive structure 102, as indicated in FIG. 8. In the present exemplary embodiment, a method of removing the liner layer 130 at the bottom of the dual damascene opening D to expose the conductive structure 102 comprises performing an etch-back process, for instance. The etch-back process is a dry etching process, for instance. It should be mentioned that not only the liner layer 130 at the bottom of the dual damascene opening D but also the insulation layer 104 underlying the dual damascene opening D is removed by performing the etch-back process, and thereby the conductive structure 102 is exposed. Namely, the etch-back process is stop on the conductive structure 102. Since the etch-back process is an isotropic etch-back process, the liner layer 130 located at the sidewall of the dual damascene opening D is left after the etch-back process is performed. A post-etch cleaning process may then be selectively performed to remove residues (e.g., organic polymer residues) in the dual damascene opening D.

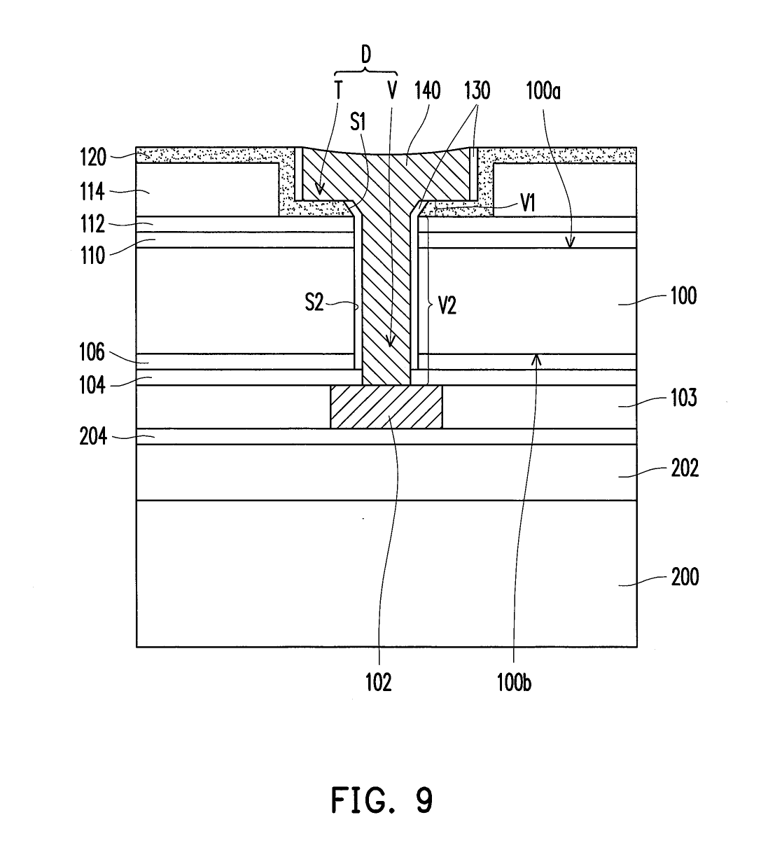

With reference to FIG. 9, the dual damascene opening D is filled with a conductive material 140 to form the dual damascene structure. The conductive material 140 in the trench T forms a conductive-line structure, and the conductive material 140 in the through hole V (TSV) forms a conductive-plug structure. A method of filling the dual damascene opening D with the conductive material 140 comprises forming the conductive material 140 in the dual damascene opening D and on the hard mask layer 120 by performing a deposition process and then removing the conductive material 140 outside the dual damascene opening D by performing a planarization process (e.g., a chemical-mechanical polishing process), so as to form the dual damascene structure. The conductive material 140 is, for instance, copper, tungsten, or any other appropriate metallic material. Additionally, in another exemplary embodiment, a seed layer and a barrier layer may be formed on a surface of the dual damascene opening D before the dual damascene opening D is filled with the conductive material 140.

After said manufacturing method is applied, the resultant dual damascene structure having the TSV comprises the substrate 100, the first dielectric layer 110, the second dielectric layer 112, the third dielectric layer 114, the hard mask layer 120, the conductive material 140, and the liner layer 130, as shown in FIG. 9.

The substrate 100 has a first surface 100a and a second surface 100b, and the conductive structure 102 is located on the second surface 100b of the substrate 100. The first dielectric layer 110, the second dielectric layer 112, and the third dielectric layer 114 are sequentially stacked on the first surface 100a of the substrate 100, and the third dielectric layer 114 has a trench T therein.

The hard mask layer 120 is located on the surface of the trench T, and the hard mask layer 120, the second dielectric layer 112, the first dielectric layer 110, and the substrate 100 have a through hole V which exposes the conductive structure 102. The through hole V communicates with the trench T to form the dual damascene opening D. Here, the through hole V has a top sidewall S1 and a bottom sidewall S2, and the top sidewall S1 is not parallel to the bottom sidewall S2.

To be more specific, the through hole V has a top through hole V1 and a bottom through hole V2. The top through hole V1 passes through the hard mask layer 120, and the sidewall S1 of the top through hole V1 is a tapered sidewall. The bottom through hole V2 passes through the second dielectric layer 112, the first dielectric layer 110, and the substrate 100, and the sidewall S2 of the bottom through hole V2 is a substantially vertical sidewall. Accordingly, the top sidewall S1 (i.e., the tapered sidewall) is not parallel to the bottom sidewall S2 (i.e., the vertical sidewall).

The dual damascene opening D is filled with the conductive material 140. The liner layer 130 is located between the conductive material 140 and the sidewall (i.e., the top sidewall S1 and the bottom sidewall S2) of the through hole V and located between the conductive material 140 and a sidewall of the trench T.

In light of the foregoing, according to the manufacturing method described in an exemplary embodiment of the disclosure, the opening O1 having the tapered sidewall S1 is formed in the hard mask layer 120. When the liner layer 130 is subsequently formed on the surface of the dual damascene opening D, the liner layer 130 may conformally cover the tapered sidewall S1. Thereby, in the process of removing the liner layer 130 at the bottom of the dual damascene opening D to expose the conductive structure 102, the corners at the top portion of the through hole V of the dual damascene opening D are not orthogonal corners and can be protected by the liner layer 130. Hence, the corners are not apt to be overly etched to expose the substrate 100. Consequently, the conductive material 140 in the dual damascene opening D may be completely isolated from the silicon substrate 100, so as to preclude short circuit.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A manufacturing method of a dual damascene structure having a through silicon via, the manufacturing method comprising:
providing a substrate, the substrate having a first surface and a second surface, a conductive structure being located on the second surface of the substrate;
sequentially forming a first dielectric layer, a second dielectric layer, and a third dielectric layer on the first surface of the substrate;
forming a trench in the third dielectric layer to expose the second dielectric layer;
forming a hard mask layer on the third dielectric layer and a surface of the trench;
forming a photoresist layer on the hard mask layer, the photoresist layer exposing the hard mask layer in the trench;
etching the hard mask layer with use of the photoresist layer as an etching mask, so as to form a first opening in the hard mask layer, wherein the first opening has a tapered sidewall;
etching the second dielectric layer and the first dielectric layer with use of the photoresist layer and the hard mask layer as an etching mask, so as to form a second opening in the second dielectric layer and the first dielectric layer;
etching the substrate exposed by the second opening and the first opening to form a through hole in the substrate;
removing the photoresist layer to form a dual damascene opening composed of the trench and the through hole;
forming a liner layer on a surface of the dual damascene opening;
removing the liner layer at a bottom of the dual damascene opening to expose the conductive structure; and
filling the dual damascene opening with a conductive material.

2. The manufacturing method as recited in claim 1, wherein the second opening substantially has a vertical sidewall.

3. The manufacturing method as recited in claim 1, wherein the tapered sidewall of the first opening and the vertical sidewall of the second opening are not parallel to each other.

4. The manufacturing method as recited in claim 1, wherein a method of removing the liner layer at the bottom of the dual damascene opening comprises performing an etch-back process.

5. The manufacturing method as recited in claim 4, wherein the liner layer at a sidewall of the dual damascene opening is left after the etch-back process is performed.

6. The manufacturing method as recited in claim 1, wherein a material of the hard mask layer and a material of the second dielectric layer are the same.

7. The manufacturing method as recited in claim 1, wherein a material of the first dielectric layer and a material of the third dielectric layer are the same.

8. The manufacturing method as recited in claim 1, wherein a material of the hard mask layer comprises amorphous silicon carbide, silicon nitride, silicon oxynitride, polyimide, tetra-ethyl-ortho-silicate oxide, benzocyclobutene, or polybenzoxazole.

9. The manufacturing method as recited in claim 1, wherein a method of forming the hard mask layer comprises plasma-enhanced chemical vapor deposition, sub-atmospheric chemical vapor deposition, high density plasma chemical vapor deposition, physical vapor deposition or spin coating.

10. The manufacturing method as recited in claim 1, wherein a method of forming the liner comprises plasma-enhanced chemical vapor deposition or low-temperature chemical vapor deposition.

11. The manufacturing method as recited in claim 1, wherein the hard mask layer has a single-layer structure or a multi-layer structure.

12. The manufacturing method as recited in claim 1, wherein the liner layer comprises an insulation material.

13. A dual damascene structure having a through silicon via, the dual damascene structure comprising:
a substrate having a first surface and a second surface, a conductive structure being located on the second surface of the substrate;
a first dielectric layer, a second dielectric layer, and a third dielectric layer sequentially stacked on the first surface of the substrate, the third dielectric layer having a trench therein;
a hard mask layer located on a surface of the trench, wherein the hard mask layer, the second dielectric layer, the first dielectric layer, and the substrate have a through hole exposing the conductive structure, the through hole communicates with the trench to form a dual damascene opening, the through hole has a top sidewall and a bottom sidewall, and the top sidewall is not parallel to the bottom sidewall;
a conductive material, the dual damascene opening being filled with the conductive material; and
a liner layer located between the conductive material and the top sidewall and the bottom sidewall of the through hole of the dual damascene opening and located between the conductive material and a sidewall of the trench of the dual damascene opening.

14. The dual damascene structure having the through silicon via as recited in claim 13, wherein the through hole has a top through hole and a bottom through hole, the top sidewall of the top through hole is a tapered sidewall, and the bottom sidewall of the bottom through hole is a substantially vertical sidewall.

15. The dual damascene structure having the through silicon via as recited in claim 14, wherein the top through hole passes through the hard mask layer, and the bottom through hole passes through the second dielectric layer, the first dielectric layer, and the substrate.

16. The dual damascene structure having the through silicon via as recited in claim 13, wherein a material of the hard mask layer and a material of the second dielectric layer are the same.

17. The dual damascene structure having the through silicon via as recited in claim 13, wherein a material of the first dielectric layer and a material of the third dielectric layer are the same.

18. The dual damascene structure having the through silicon via as recited in claim 13, wherein a material of the hard mask layer comprises amorphous silicon carbide, silicon nitride, silicon oxynitride, polyimide, tetra-ethyl-ortho-silicate oxide, benzocyclobutene, or polybenzoxazole.

19. The dual damascene structure having the through silicon via as recited in claim 13, wherein the hard mask layer has a single-layer structure or a multi-layer structure.

20. The dual damascene structure having the through silicon via as recited in claim 13, wherein the liner layer comprises an insulation material.
